(19) United States
(12) Patent Application Publication
(10) Pub. No.: US 2019/0104612 A1
(43) Pub. Date: Apr. 4, 2019

(54) POLYMER MATRIX COMPOSITE FOR ELIMINATING SKEW AND FIBER WEAVE EFFECT

(71) Applicant: ITEQ CORPORATION, Hsinchu County (TW)

(72) Inventor: TARUN AMLA, San Jose, CA (US)

(21) Appl. No.: 15/956,208

(22) Filed: Apr. 18, 2018

Related U.S. Application Data
(60) Provisional application No. 62/565,538, filed on Sep. 29, 2017.

(51) Int. Cl. H05K 1/03; B32B 15/20; B32B 15/14; B32B 37/20; B32B 37/06; B32B 5/02; B32B 5/26; B32B 7/12; H05K 1/02

(52) U.S. Cl. CPC H05K 1/0366; H05K 2201/0141; B32B 15/14; B32B 37/20; B32B 37/06; B32B 5/022; B32B 5/024; B32B 5/26; B32B 7/12; H05K 1/024; H05K 1/0373; B32B 2262/0238; B32B 2262/105; B32B 2262/101; B32B 2457/08; B32B 2260/046; B32B 2311/12; B32B 2315/085; B32B 2315/02; B32B 2327/18; B32B 2307/204; B32B 2260/021; B32B 2305/076; H05K 2201/012; H05K 2201/015; B32B 15/20

(57) ABSTRACT

The present disclosure provides a polymer matrix composite, and a laminate, a prepreg and a printed circuit board using the same. The polymer matrix composite includes a polymeric resin and a non-woven reinforcing material having a dielectric constant of from about 1.5 to about 4.8 and a dissipation factor at 10 GHz below 0.003. The printed circuit board uses the laminate including the polymer matrix as a core layer which is sandwiched between at least two outer layers.

### CROSS REFERENCE TO RELATED APPLICATION

This application claims priority to U.S. Provisional Patent Application No. 62/565,538, filed Sep. 29, 2017, entitled “ELIMINATING FIBER WEAVE EFFECT AND SKEW THROUGH USE OF LOW DK ORGANIC AND INORGANIC NONWOVEN REINFORCEMENTS”, the contents of which are herein incorporated by reference in its entirety.

### BACKGROUND

### 1. Technical Field

The present disclosure relates to a polymer matrix composite, and in particular, to a polymer matrix composite for eliminating skew and fiber weaves effect.

### 2. Description of Related Art

Printed circuit boards (PCB) are generally manufactured with dielectric materials such as woven glass materials impregnated in a polymer matrix. The composite formed by the woven glass materials impregnated in the polymer matrix is clad on one or both sides with copper for forming laminates used in PCB applications.

In most applications, the polymer matrix is epoxy resin or modified epoxy resin; polyimides, bismaleimide triazine, cyanate ester and poly phenylene ether type polymers may also be used. In certain radio frequency (RF) applications, polybutadiene, polyisoprene and the derivatives thereof are used with hardeners, accelerators and additives such as fillers and flame retardants. While the woven glass materials in most cases is E-glass, the use of L-glass and other low dielectric constant (Dk) and specialty type glass is increasing, such as the use of S-glass and T-glass for some specialized applications.

The difference in permittivity or dielectric constant between glass and the polymer matrix is very significant. In the case of E-glass, which is more commonly used, the Dk thereof is above 6.0 (depending on the frequency of measurement), while the Dk of polymers used as matrix are typically around 3.0, thereby presenting a non-homogeneous medium for signal propagation.

Printed circuit boards are used today in a number of high speed digital communications applications and are a major means of routing, switching and storing data. To keep pace with the explosive and exponential growth of the Internet, the demand for faster data rates keeps on increasing. Essentially, this means that more data are sent through every channel—a channel being a transmission line on circuit boards. The data is encoded in high frequency waveforms, with typically 2 or 4 bits encoded per waveform. In the case of 2 bits per waveform, the technique currently used is called NRZ or PAM2 (i.e., 2 Level-Pulse amplitude modulation) and in the case of 4 bits per waveform, the PAM4 (i.e., 4 Level-Pulse amplitude modulation) technique is used. Differential signaling is used where one transmission line acts as a reference to the others. A benefit of using differential signaling is a lower Nyquist frequency: the Nyquist or carrier frequency is half the data rate when NRZ signaling is used, and ¼th the data rate when PAM4 is used. For single ended lines (where the data is sent through a single line), higher frequency harmonics are needed; for example, frequency components as high as 70 GHz (5th harmonic of the fundamental frequency) are required for sending 28 Gbps (gigabits per second—10⁹ bits per second). The problem with such high frequency is that the signal amplitude loss in the dielectric is a direct function of the frequency and the conductor, or that copper losses are a function of the square root of the frequency.

The speed of propagation of the electromagnetic wave in a medium is inversely proportional to the square root of the permittivity. In other words, the higher the permittivity, the slower the signal. In typical backplane applications, the length of the channel is very long, and can be as high as a meter or more. Since the current technology relies on woven glass reinforced laminates, the material including reinforcement and resin would be heterogeneous. Therefore, two transmission lines separated by a space and forming a differential pair would generally traverse paths with different permittivity, leading to a delay of the signal that is on the path with higher permittivity. This phenomenon is known as “skew” in digital engineering parlance. With the industry shift in the direction of PAM4 (and potentially PAM8 and higher) signaling, skewing has become an even more important factor in signal transmission.

There are many ways to mitigate the skew, chief among them being the use of lines routed at an angle. This is an effective, but very inefficient use of the prime space on the board, and again leads to wasted areas and additional scrap, while still causing significant skew. Using multiple plies of prepreg to statistically average out the variation in dielectric constants is also not very effective, as such an approach increases board thickness and still does not solve the problem completely.

Use of flat glass, spread glass or glass with an even lower Dk compared to the >6.0 of E-glass, e.g., around 4.8, is helpful but does not completely solve the problem either. Use of un-reinforced thermoplastic sheets is also limited in effectiveness due to poor mechanical and thermal properties, making these products unsuitable for fabrication of most boards, as they typically require high temperature excursions beyond the capabilities of these materials.

### SUMMARY

The present disclosure is directed to a polymer matrix composite for alleviating the drawbacks associated with the skew and fiber weave effect by using a non-woven reinforcing material having a specific range of Dk and dissipation factor.

An embodiment of the present disclosure provides a polymer matrix composite including a polymeric resin and a non-woven reinforcing material having a dielectric constant of from about 1.5 to about 4.8 and a dissipation factor at 10 GHz below 0.003.

Another embodiment of the present disclosures provides a laminate including at least a reinforcement layer formed by the polymer matrix composite as mentioned above.

Yet another embodiment of the present disclosure provides a prepreg including a resin portion which is partially cured and impregnated with a non-woven reinforcing material having a dielectric constant of from about 1.5 to about 4.8 and a dissipation factor at 10 GHz below 0.003.

Still another embodiment of the present disclosure provides a printed circuit board including at least two outer layers and a core layer sandwiched between the at least two outer layers. The core layer includes the laminate as mentioned above.

One of the advantages of the present disclosure is that products such as printed circuit board formed by using the polymer matrix composite of the present disclosure can be skew-free by the technical feature of using “a non-woven reinforcing material having a dielectric constant of from about 1.5 to about 4.8 and a dissipation factor at 10 GHz below 0.003”.

In order to further understand the techniques, means and effects of the present disclosure, the following detailed descriptions and appended drawings are hereby referred to, such that, and through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 is a sectional schematic view of a laminate provided by an embodiment of the present disclosure.

FIG. 2 is a sectional schematic view of a printed circuit board provided by an embodiment of the present disclosure.

### DESCRIPTION OF THE EXEMPLARY EMBODIMENTS

Reference will now be made in detail to the exemplary embodiments of the present disclosure, examples of which are illustrated in the accompanying drawings. Wherever possible, the same reference numbers are used in the drawings and the description to refer to the same or like parts.

An embodiment of the present disclosure provides a polymer matrix composite that may be used in the electronics industry. The polymer matrix polymer can include a polymeric resin and a non-woven reinforcing material. The polymeric resin is used as the matrix, and the non-woven reinforcing material can be impregnated or coated in the polymeric resin. The non woven reinforcement is random and continuous and therefore does not create areas of heterogeneity as compared to woven fabric which is not random and homogeneous.

The polymeric resin used in the present disclosure can include one or more base resins known to be useful in manufacturing prepreg and laminate materials. The base resin will typically be a thermoset or thermoplastic resin, such as but not limited to, epoxy resins, polyphenylene ether based resins, cyanurate resins, bismaleimide resins, polyimide resins, phenolic resins, furan resins, xylene formaldehyde resins, ketone formaldehyde resins, urea resins, melamine resins, aniline resins, alkyd resins, unsaturated polyester resins, diallyl phthalate resins, triallyl cyanurate resins, triazine resins, polyurethane resins, silicone resins and any combination or mixture thereof. In an embodiment of the present disclosure, the polymeric resin has a dielectric constant of about 3.0. However, the present disclosure is not limited in this respect.

Specifically, in an embodiment of the present disclosure, the polymeric resin is or includes an epoxy resin. Some examples of epoxy resins include phenol-type epoxy resin such as those based on the diglycidyl ether of bisphenol A, based on polyglycidyl ethers of phenol-formaldehyde novolac or cresol-formaldehyde novolac, based on the triglycidyl ether of tris(p-hydroxyphenol)methane, or based on the tetraglycidyl ether of tetraphenylethane; amine types such as those based on tetraglycidyl-methylenedianiline or on the triglycidyl ether of p-aminoglycol; and cycloaliphatic types such as those based on 3,4-epoxycyclohexylmethyl-3,4-epoxycyclohexane carboxylate. The term “epoxy resin” also refers to reaction products of compounds containing an excess of epoxy (e.g., epoxies of the aforementioned types) and aromatic dihydroxy compounds. These compounds may be halogen-substituted. In a preferred embodiment of the present disclosure, the polymeric resin includes epoxy-resins which are derivative of bisphenol A, particularly FR-4. FR-4 is made by an advancing reaction of an excess of bisphenol A diglydicyl ether with tetrabromobisphenol A. Mixtures of epoxy resins with bismaleimide resin, cyanate resin and/or bismaleimide triazine resin can also be used in the embodiments of the present disclosure.

The non-woven reinforcing material can have a dielectric constant of from about 1.5 to about 4.8 and a dissipation factor at 10 GHz below 0.003. In a preferred embodiment of the present disclosure, the dielectric constant of the non-woven reinforcing material is from about 1.8 to 4.8. The range of the dielectric constant mentioned above is measured before the non-woven reinforcing material is combined with the polymeric resin to form a resin impregnated reinforcing material and/or before they are incorporated into a reinforced prepreg and/or laminate. The “dielectric constants” discussed herein and the dielectric constant ranges or values referred to herein are determined by the Bereskin test method, or alternatively by the slit post method.

Specifically, since the PCB industry typically requires a DK of around 3.0-3.5, it is advantageous to have the DK of the reinforcement below 4.8 so as to achieve a low Dielectric constant for the overall laminate.

The non-woven reinforcing material may be any sheet or ground materials that can be used for manufacturing substrate sheets for fabricating a prepreg or laminate used in the manufacture of printed circuit boards. In a preferred embodiment, the non-woven reinforcing material is a sheet material.

For example, the non-woven reinforcing material can include a material selected from polytetrafluoroethylene (PTFE), quartz, glass material, Liquid Crystal Polymers and any combination thereof. Specifically, the non-woven reinforcing material may be a non-woven PTFE mat/paper optionally blended with other ingredients and binder(s), a non-woven quartz mat/paper or a Liquid crystal polymer. For example, the ingredients may include chopped PTFE fibers, chopped glass fibers, fillers such as boron nitride and fused silica.

The amount of non-woven reinforcing material may vary depending on the requirements of the product manufactured using the polymer matrix composite. For example, based on the total weight of the polymer matrix composite, the content of the non-woven reinforcing material can range from about 5% to about 70%, and preferably from about 5% to about 60%. In addition, based on the total weight of the polymer matrix composite, the content of the polymeric resin including fillers and flame retardants and other additives can range from about 95% to about 30%, and preferably from about 95% to about 40%.

In an embodiment of the present disclosure, the non-woven reinforcing material is subjected to a surface enhancement treatment for improving its adhesion to the polymeric resin. The surface enhancement treatment can includes a corona treatment or a use of a coupling agent.

In the embodiments of the present disclosure, the polymer matrix composite can further include at least one of a woven reinforcing material, a micro-sized filler, a nano-sized filler, an organic chopped fiber, an inorganic chopped fiber, a flame retardant, a solvent, and other additives.

For example, the woven reinforcing material can include: inorganic fiber cloth including various glass cloth (e.g., roving cloth, cloth, a chopped mat, and a surfacing mat), metal fiber cloth, and the like; woven cloth made of liquid crystal fiber (e.g., wholly aromatic polyamide fiber, wholly aromatic polyester fiber, and polybenzazole fiber); woven cloth made of synthetic fiber (e.g., polyvinyl alcohol fiber, polyester fiber, and acrylic fiber); natural fiber cloth (e.g., cotton cloth, hemp cloth, and felt); carbon fiber cloth; and natural cellulosic cloth (e.g., craft paper, cotton paper, and paper-glass combined fiber paper).

In an embodiment of the present disclosure, the woven reinforcing material is a woven glass fabric material having a dielectric constant of from about 3.5 to 7.0 or greater, such as low Dk glass having a dielectric constant of from 3.5 to about 4.5, E-glass, R-glass, ECR-glass, 5-glass, C-glass, Q-glass and any other woven glass fabric of the kind known to be useful in preparing glass fabric reinforced prepregs and laminates.

Other additives of the composite may include initiators or catalysts. Examples of the initiators or catalysts include, but are not limited to, peroxide or azo-type polymerization initiators. In general, the initiators or catalysts chosen may be any compound that is known to be useful in resin synthesis or curing, whether or not it performs one of these functions.

The flame retardant may be any flame retardant material that is known to be useful in the polymer matrix composite used to manufacture prepregs and laminates. The flame retardant may contain halogens or may be halogen free. Alternatively or additionally, the polymer matrix composite may include halogens such as bromine to impart the cured resin with flame retardant properties.

The solvent that may be included in the polymer matrix composite is typically used to solubilize the component in the polymer matrix composite, so as to control the viscosity of the polymer matrix composite and/or to maintain a component, such as the non-woven reinforcing material, in a suspended dispersion. In this case, any solvent known by one of skill in the art to be useful in conjunction with thermosetting resin systems can be used. For example, the solvent can include methylethylketone (MEK), toluene, dimethylformamide (DMF), or any mixtures thereof.

The polymer matrix composite may further include a variety of other optional components including fillers, tougheners, adhesion promoters, defoaming agents, leveling agents, dyes, and pigments. For example, a fluorescent dye can be added to the polymer matrix composite in a trace amount to cause a laminate prepared therefrom to fluoresce when exposed to UV light under an optical inspection equipment at retail.

It should be noted that the resin compositions are used to manufacture prepregs and laminates. During the manufacturing process, the non-woven reinforcing materials are impregnated with or otherwise associated with the polymeric resin, optional additives and solvent mentioned above, and most of the solvent is removed from the polymer matrix composite to form the prepregs and laminates.

The polymer matrix composite described above is especially useful for preparing prepregs and/or laminates used in the manufacture of printed circuit boards. The laminates can be partially cured or b-staged to form what is known in the industry as a prepreg—in which state they can be laid up with additional material sheets to form a c-staged or fully cured laminate sheet. Alternatively, the resins can be manufactured into c-staged or fully cured material sheets.

In an embodiment of the present disclosure, the polymer matrix composite provided by the present disclosure is useful for making prepregs in batch or in a continuous process. Prepregs are generally manufactured using a core material such as a roll of woven glass web (fabric) which is unwound into a series of drive rolls. The web then passes into a coating area where the web is passed through a tank containing the thermosetting resin system (including the polymeric resin), solvent and other components, where the glass web becomes saturated with the polymeric resin. The saturated glass web is then passed through a pair of metering rolls which remove excess polymeric resin from the saturated glass web and thereafter, the polymeric resin-coated web travels the length of a drying tower for a predetermined period of time until the solvent is evaporated from the web. A second and subsequent coating of resin can be applied to the web by repeating these steps until the preparation of the prepreg is complete, whereupon the prepreg is wound onto the roll. The woven glass web can be replaced with a woven fabric material, paper, plastic sheets, felt, and/or particulate materials such as glass fiber particles or particulate materials.

In another process for manufacturing prepreg or laminate materials, the components of the polymer matrix composite are premixed in a mixing vessel under ambient temperature and pressure. The viscosity of the pre-mix is about 600-1000 cps and can be adjusted by adding or removing solvent from the pre-mix. Fabric substrate such as E-glass is pulled through a dip tank including the premixed polymer matrix composite, through an oven tower where excess solvent is driven off and the prepreg is rolled or sheeted to size, layered up between copper (Cu) foil in various constructions depending on glass weave style, resin content and thickness requirements.

The polymer matrix composition can also be applied in a thin layer to a Cu foil substrate (RCC—resin coated Cu) using slot-die or other related coating techniques.

The polymer matrix composite, prepregs and resin coated copper foil sheets described above can be used to make laminates, such as those used to manufacture printed circuit boards, in batch or in continuous processes.

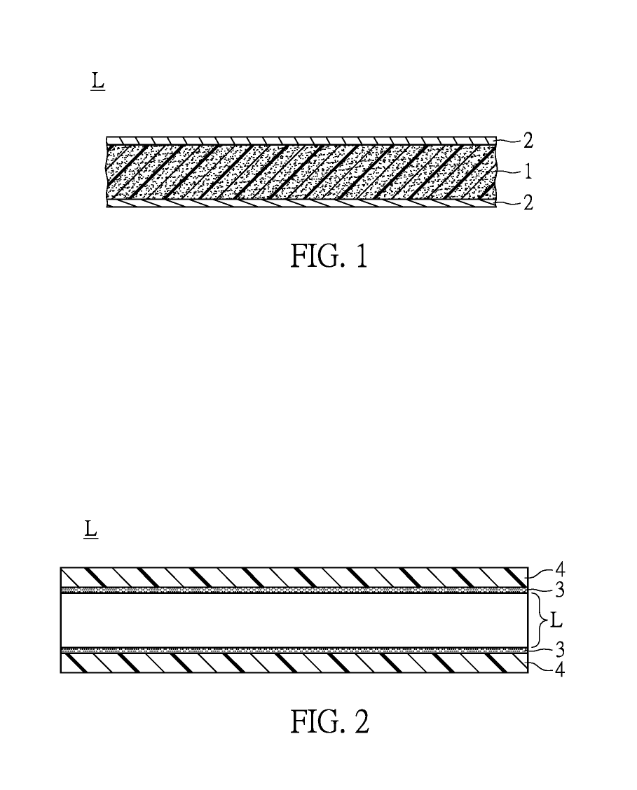

Reference is made to FIG. 1. FIG. 1 is a sectional schematic view of a laminate provided by an embodiment of the present disclosure. As shown in FIG. 1, the laminate L provided by an embodiment of the present disclosure includes a reinforcing layer 1 made of the polymer matrix composite as mentioned above, and two metal layers 2 such as copper foils. In the present disclosure, the laminate L can include the reinforcing layer 1 and at least a metal layer 2 disposed on the reinforcement layer 1. It should be noted that in the present disclosure, the metal layer 2 can be substituted by a non-metal layer In addition, the laminate L may further include a fabric layer (not shown) to allow the polymeric resin in the polymer matrix composite to impregnate thereinto.

In another embodiment of the present disclosure, the laminate L can be formed by single or multiple layers of the reinforcing layer to form an unclad laminate.

In an exemplary continuous process for manufacturing laminates provided by the embodiments of the present disclosure, a continuous sheet in the form of each of copper (the outer layer 2), a prepreg (for forming the reinforcing layer 1) and a thin fabric sheet are continuously unwound into a series of drive rolls to form a layered web of fabric that is adjacent to the prepreg sheet and that is adjacent to a copper foil sheet, such that the prepreg sheet lies between the copper foil sheet and the fabric sheet. The web is then subjected to heat and pressure conditions for a time that is sufficient to cause the resin in the prepreg to migrate into the fabric material and to completely cure the resin. In the resulting laminate, the migration of the resin into the fabric causes the thickness of the resin layer (the distance between the copper foil material and the fabric sheet material) to diminish and approach zero as combination layers discussed above transforms from a web of three layers into a single laminate sheet. In an alternative to this method, a single prepreg resin sheet can be applied to one side of the fabric material layer and the combination sandwiched between two copper layers after which heat and/or pressure is applied to the layup to cause the resin material to flow and thoroughly impregnate the fabric layer and cause both copper foil layers to adhere to the central laminate.

In another embodiment of the present disclosure, polymer matrix composite coated copper sheets can be made at the same time the laminate is being made by applying a thin coating of the polymer matrix composite to two different continuously moving copper sheets, removing any excess polymer matrix composite from the sheets to control the thickness and then partially curing the resin under heat and/or pressure conditions to form a sheet of b-staged resin coated copper. The sheet(s) of b-staged resin coated copper can then be used directly in the laminate manufacturing process.

In yet another embodiment of the present disclosure, the fabric material—with or without prior pretreatment—can be continuously fed into a bath containing the polymer matrix composite provided by the present disclosure such that the fabric material becomes impregnated with the polymer matrix composite. The polymer matrix composite can be optionally partially cured at this stage in the process. Next, one or two copper foil layers can be associated with the first and/or second planar surface of the polymer matrix composite impregnated fabric sheet to form a web after which heat and/or pressure is applied to the web to fully cure the polymer matrix composite.

The present disclosure further provides a printed circuit board manufactured by the use of the laminate and the prepreg mentioned above. With reference made to FIG. 2, a sectional schematic view of a printed circuit board provided by an embodiment of the present disclosure is shown. The printed circuit board B of FIG. 2 includes a laminate L as a core layer, two outer layers 4 sandwiching the laminate L, and two bonding sheets 3 disposed between the laminate L and the two outer layers 4.

The laminate L used as the core layer can be the laminate L including a reinforcing layer 1 and at least a metal layer 2 (or a non-metal layer) as mentioned above. The bonding sheets 3 can be formed by the prepreg mentioned above. In other words, the prepreg can be made of the polymer matrix composite which contains a non-woven reinforcing material having a dielectric constant of from about 1.5 to about 4.8 and a dissipation factor at 10 GHz below 0.003.

In summary, one advantage of the present disclosure is that products such as a printed circuit board formed by using the polymer matrix composite of the present disclosure can be skew-free by the technical feature of using “a non-woven reinforcing material having a dielectric constant of from about 1.5 to about 4.8 and a dissipation factor at 10 GHz below 0.003”.

The above-mentioned descriptions represent merely the exemplary embodiment of the present disclosure, without any intention to limit the scope of the present disclosure thereto. Various equivalent changes, alterations or modifications based on the claims of the present disclosure are all consequently viewed as being embraced by the scope of the present disclosure.

What is claimed is:

1. A polymer matrix composite, comprising:
a polymeric resin; and
a non-woven reinforcing material having a dielectric constant of from about 1.5 to about 4.8 and a dissipation factor at 10 GHz below 0.003.

2. The polymer matrix composite according to claim 1, further comprising at least one of a woven reinforcing material, a micro-sized filler, a nano-sized filler, an organic chopped fiber, an inorganic chopped fiber and a flame retardant.

3. The polymer matrix composite according to claim 2, wherein the flame retardant is a halogen-containing flame retardant.

4. The polymer matrix composite according to claim 1, wherein the non-woven reinforcing material is subjected to a surface enhancement treatment.

5. The polymer matrix composite according to claim 1, wherein the non-woven reinforcing material is polytetrafluoroethylene.

6. The polymer matrix composite according to claim 1, wherein the non-woven reinforcing material comprises a liquid crystal polymer.

7. The polymer matrix composite according to claim 1, wherein the non-woven reinforcing material is quartz.

8. The polymer matrix composite according to claim 1, wherein the non-woven reinforcing material is glass.

9. A prepreg comprising a resin portion that is partially cured and impregnated with a non-woven reinforcing material having a dielectric constant of from about 1.5 to about 4.8 and a dissipation factor at 10 GHz below 0.003.

10. A printed circuit board, comprising:
at least two outer layers; and
a core layer sandwiched between the at least two outer layers;
wherein the core layer includes a laminate, the laminate comprising at least a reinforcement layer formed by the polymer matrix composite according to claim 1.

11. The printed circuit board according to claim 10, further comprising a bonding sheet disposed between the at least two outer layers and the core layer, wherein the bonding sheet is formed by a prepreg including a resin portion that is partially cured and impregnated with a non-woven reinforcing material having a dielectric constant of from about 1.5 to about 4.8 and a dissipation factor at 10 GHz below 0.003.

12. The printed circuit board according to claim 10, wherein the laminate further comprises at least a metal layer disposed on the reinforcement layer.
